(19) United States
(12) Patent Application Publication
(10) Pub. No.: US 2013/0040258 A1
(43) Pub. Date: Feb. 14, 2013

(54) HEATING CHAMBER HAVING REACTION PREVENTING LAYER AND LAYER FORMING METHOD THEREOF

(71) Applicants: MING-HUI YU, TAIPEI CITY (TW); A-TZU CHEN, NEW TAIPEI CITY (TW); CHANG-FA CHEN, TAOYUAN COUNTY (TW); WANG-TSUNG LIANG, TAOYUAN COUNTY (TW); LIANG-JAN CHANG, Taoyuan County (TW)

(72) Inventors: MING-HUI YU, TAIPEI CITY (TW); A-TZU CHEN, NEW TAIPEI CITY (TW); CHANG-FA CHEN, TAOYUAN COUNTY (TW); WANG-TSUNG LIANG, TAOYUAN COUNTY (TW); LIANG-JAN CHANG, Taoyuan County (TW)

(73) Assignee: TANGTECK EQUIPMENT INC., Taoyuan County (TW)

(21) Appl. No.: 13/207,476

(22) Filed: Aug. 11, 2011

(51) Int. Cl. F27D 1/00; C23C 16/02

(52) U.S. Cl. 432/120; 427/255.28; 427/255.391; 427/190

(57) ABSTRACT

The instant disclosure relates to an improved heating chamber of a heating device having a non-reactive surface layer. The heating chamber includes at least one metal layer and at least one non-reactive disposed thereon. The improved heating chamber is protected against reacting chemically during the thermal treatment process, and has better anti-corrosion capability. The heating chamber is also protected against cracking. Therefore, the service life of the heating chamber is extended. A heating device having improved heating chamber and at least one method of forming the non-reactive layer are also disclosed.

### BACKGROUND OF THE INVENTION

1. Field of the Invention

The instant disclosure relates to a heating chamber having reaction preventing layer (non-reactive layer); more particularly, to an improved heating chamber having a non-reactive surface layer and a method of forming the non-reactive layer.

2. Description of Related Art

Industrial heating devices, such as furnaces, are equipped with internal chambers to receive objects for heat treatment. The chamber is usually made of metallic material having high temperature endurance. However, when the furnace begins to heat up, special gases may be purposely introduced into the chamber, where chemical reactions are expected to occur with the disposed objects. Being exposed to high temperature and reactant gases, the chemical reaction will inevitably occur on the inner surface of the chamber, and the chamber itself tends to be corroded and crack due to brittleness. Consequently, the service life of the chamber itself is shortened.

To address the above issues, the inventor strives via industrial experience and academic research to present the instant disclosure, which can effectively improve the limitations described above.

### SUMMARY OF THE INVENTION

The instant disclosure provides an improved heating chamber having a non-reactive layer, a heating device having the improved heating chamber, and at least one method of forming the non-reactive layer. Thereby, the heating chamber can have improved anti-corrosion ability and protection against cracking Thus, a longer service life can be expected.

The heating chamber comprises at least one metal layer and at least one non-reactive layer disposed thereon.

The heating device comprises a main body having a heating chamber formed internally. The heating chamber includes at least one metal layer and at least one non-reactive layer disposed thereon.

The method of forming the non-reactive layer has the following steps: cleaning the bonding surface of a metal layer of the heating chamber; drying the metal layer surface by forced convection; vacuuming the heating chamber; introducing reactive gases into the heating chamber; and heating reactive gases to a reactive temperature, allowing a non-reactive layer to be formed over the metal layer.

An alternative method of forming the non-reactive layer has the following steps: cleaning the bonding surface of a metal layer of the heating chamber; drying the metal layer surface by forced convection; spray coating the metal layer surface with ceramic powders; and heating the chamber to a sintering temperature in forming a non-reactive layer over the metal layer.

The instant disclosure has the following advantages. Namely, the presence of the non-reactive layer protects the heating chamber from reacting chemically during the thermal treatment process. The chamber can have improved anti-corrosion capability and added resistance against cracking Thus, a longer service life can be expected.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 is a schematic view of a heating device of the instant disclosure.

FIG. 2 is a partial sectional view of a heating chamber of the heating device for a first embodiment of the instant disclosure.

FIG. 3 is a partial sectional view of a heating chamber of the heating device for a second embodiment of the instant disclosure.

FIG. 4 is an overview of a heating chamber of the heating device for a third embodiment of the instant disclosure.

FIG. 5 is an overview of a heating chamber of the heating device for a fourth embodiment of the instant disclosure.

FIG. 6 is a flow chart showing a method of forming a non-reactive layer on the inner surface of the heating chamber.

FIG. 7 is a flow chart showing an alternative method of forming the non-reactive layer on the inner surface the heating chamber.

### DETAILED DESCRIPTION OF PREFERRED EMBODIMENTS

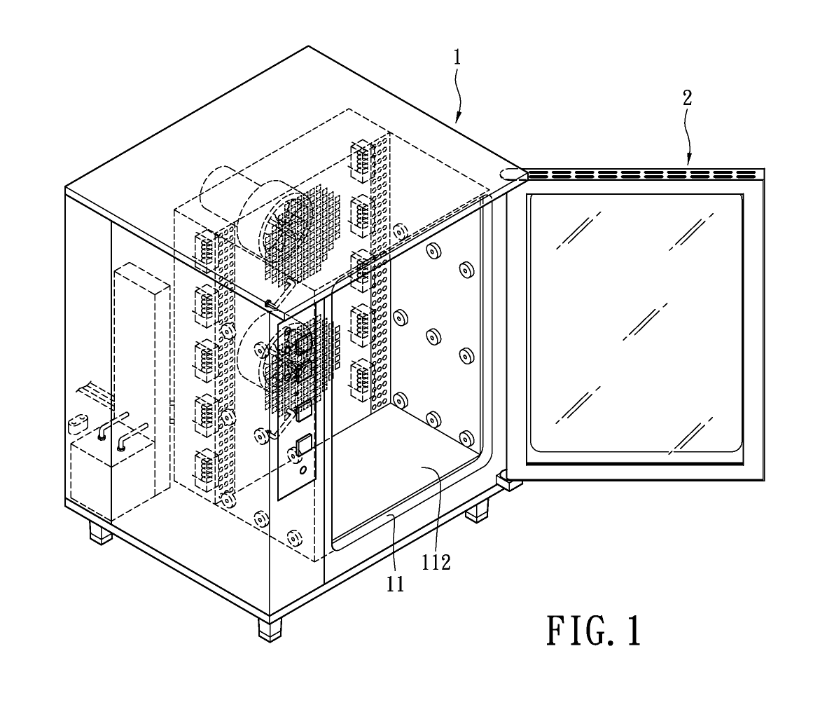

Please refer to FIG. 1, which shows a heating chamber having a non-reactive layer of the instant disclosure. The heating chamber can be adapted in a variety of heating devices. For explaining purposes, a box-shaped heating device is disclosed herein. The heating device having a main body 1, a door 2, and a heating chamber 11 formed inside the main body 1 for receiving loads to undergo thermal treatment. The door 2 is hinged on the front edge portion of the main body 1 for opening and closing the heating chamber 11. The heating chamber 11 may be a variety of geometric shapes, including rectangular, circular, or polygonal. The heating chamber 11 can also include furnace tubes or working tubes. For the instant embodiment, the heating chamber 11 is rectangular-shaped. At least one heater (not labeled) is arranged on the main body 1 for heating.

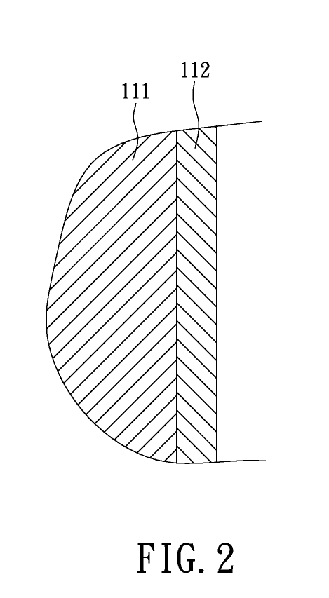

Please refer to FIG. 2, which shows the heating chamber 11 having at least one metal layer 111 coated with at least one non-reactive layer 112. The metal layer 111 can be made of stainless or other metallic materials. The non-reactive layer 112 can be made of nitride, carbide, oxide, or boride. In other words, the non-reactive layer 112 may be a nitride, carbide, oxide, or a boride film. For the instant embodiment, the non-reactive layer 112 is made of titanium nitride (TiN), but is not restricted thereto.

The thickness of the non-reactive layer 112 is not restricted, which can be a thin or thick film depending on the application. The non-reactive layer 112 can be coated onto the metal layer 111 by spraying, thermal spraying, plasma spraying, or physical/chemical deposition. The non-reactive layer 112 can have plate-like shape and be arranged onto the metal layer 111. The technique of disposing the non-reactive layer 112 is not restricted.

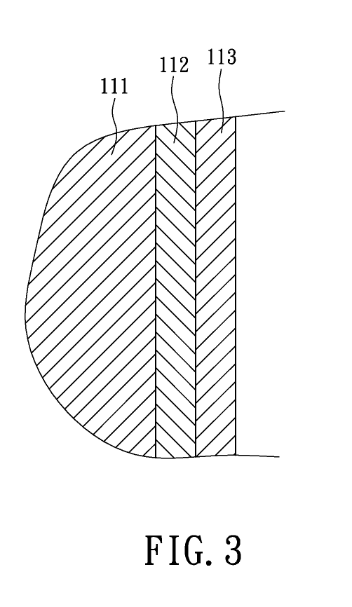

Please refer to FIG. 3, which shows the heating chamber 11 can further include a protecting layer 113. The protecting layer 113 can be a glaze, which is shiny, wear-resistant, and high-temperature resistant. The protecting layer 113 is disposed on the non-reactive layer 112 and can be bonded by heat treatment. The protecting layer 113 increases the protection capability and fills any potential surface crevices of the non-reactive layer 112. Other benefits include enhancing high-temperature resistance and anti-corrosion capability.

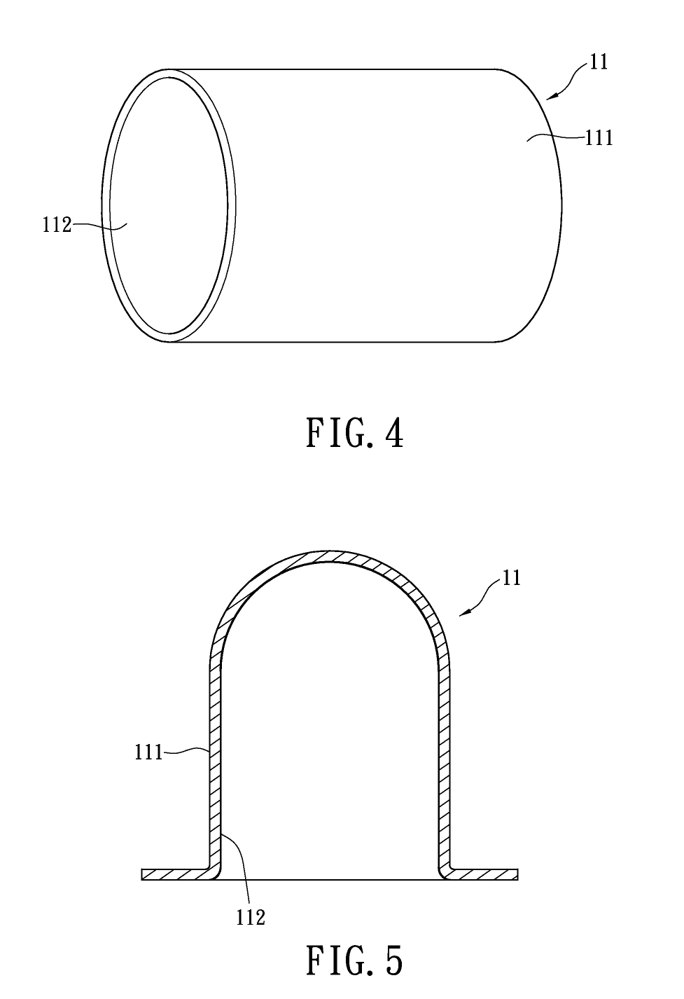

Please refer to FIGS. 4 and 5, which show two embodiments of the heating chamber 11 having a tubular shape and an inverted bucket-like shape, respectively. Each heating chamber 11 has at least one metal layer 111 covered with at least one non-reactive layer 112.

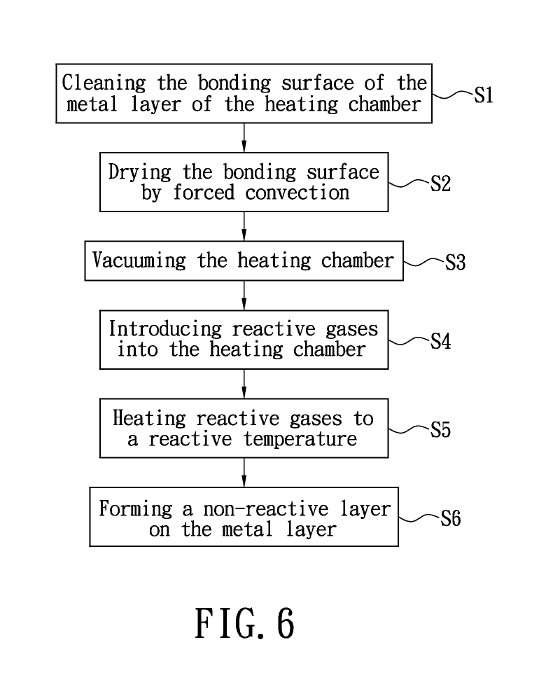

Please refer to FIG. 6, which shows the steps of a method for forming the non-reactive layer for the heating chamber. The method mainly utilizes the chemical vapor deposition technique with the following steps (please refer to FIGS. 1, 2, and 6). First, use weak acid or weak base to wash and clean the bonding surface of the metal layer 111 (step S1). Next, use nitrogen, argon, or dry air to dry the bonding surface by forced convection (step S2). Then, the heating chamber 11 is vacuumed (step S3), followed by introducing various reactive gases into the heating chamber 11 (step S4). The gases include hydrogen (H₂), nitrogen (N₂), titanium tetrachloride (TiCl₄), and ammonia (NH₃). For each preceding gas, the ratio is 30˜50 vol. % for hydrogen (e.g. 35˜40 vol. %), 30˜50 vol. % for nitrogen (e.g. 35˜40 vol. %), 0.1˜5.0 vol. % for titanium tetrachloride (e.g. 0.5˜1.0 vol. %), and 1˜25 vol. % for ammonia (e.g. 5˜10 vol. %). Then, these reactive gases are heated to a reactive temperature of 600˜700 degree Celsius (step S5). At this temperature, the metal layer 111 of the heating chamber 11 would react with the reactive gases in forming the titanium nitride layer, or the non-reactive layer 112, above its surface (step S6).

The abovementioned steps can be completed prior to assemble the heating chamber 11 to the heating device. If such option is chosen, the vacuuming and delivering/heating of reactive gases need to be completed by other apparatuses. Alternatively, these steps can also be carried out after the heating chamber 11 has been assembled to the heating device. With such option, the procedures of vacuuming and delivering/heating of reactive gases can be done with the heating device itself.

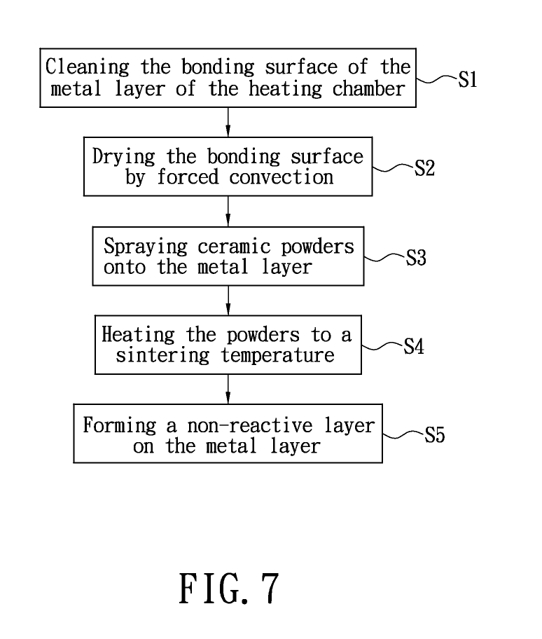

Please refer to FIG. 7, which explains an alternative method for forming the non-reactive layer. The method involves spray coating and sintering with the following steps (please refers to FIGS. 1, 2, and 7). First, use weak acid or weak base to wash and clean the bonding surface of the metal layer 111 (step S1). Next, use nitrogen, argon, or dry air to dry the bonding surface by forced convection (step S2). Then, ceramic powders are sprayed over the metal layer 111 of the heating chamber 11 (step S3). The composition of the ceramic powders may include kaolin (5˜10 wt. %), feldspar (20˜80 wt. %), limestone (1˜40 wt. %), dolomite (1˜15 wt. %), wollastonite (5˜10 wt. %), corundum (1˜15 wt. %), and quartz (1˜50 wt. %). These ceramic raw materials are grind into fine powders and mixed uniformly. Then, the ceramic powders are heated to a sintering temperature of approximately 1000˜1400 deg. Celsius (step S4). For example, the non-reactive layer 112 (glazed layer) can be formed at a sintering temperature of 1200 deg. Celsius (step S5).

By overlaying the metal layer 111 for the heating chamber of the heating device with the non-reactive layer, the heating chamber can be protected from chemical reaction. The anti-corrosion capability of the heating chamber is enhanced. When special gases or inert gases are introduced, the heating chamber is better protected against chemical reactions. In addition, the non-reactive layer 112 enhances the structural strength of the heating chamber by preventing the formation of cracks due to brittleness, thus a longer service life can be expected.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. An improved heating chamber of a heating device, comprising:
a metal layer; and
a non-reactive layer coated on the metal layer.

2. The improved heating chamber of a heating device of claim 1, wherein the non-reactive layer is selected from a group consisting of nitride layer, carbide layer, oxide layer, and boride layer.

3. The improved heating chamber of a heating device of claim 1, wherein the non-reactive layer is a titanium nitride layer.

4. The improved heating chamber of a heating device of claim 1, wherein a protecting layer is further disposed on the non-reactive layer.

5. A heating device, comprising:
a main body having a heating chamber formed therein, wherein the heating chamber comprises
a metal layer; and
a non-reactive layer coated on the metal layer.

6. The heating device of claim 5, wherein the non-reactive layer is selected from a group consisting of nitride layer, carbide layer, oxide layer, and boride layer.

7. The heating device of claim 5, wherein the non-reactive layer is a titanium nitride layer.

8. The heating device of claim 5, wherein a protecting layer is further disposed on the non-reactive layer.

9. A method of forming a non-reactive layer on a metal layer of a heating chamber, comprising the steps of:
cleaning the surface of the metal layer of the heating chamber;
drying the metal layer surface by forced convection;
vacuuming the heating chamber to expose the metal layer in a substantially vacuum environment;
introducing reactive gases into the heating chamber; and
heating the reactive gases to a reactive temperature in forming the non-reactive layer on the metal layer.

10. The method of forming a non-reactive layer on a metal layer of a heating chamber of claim 9, wherein the metal layer surface is dried by forced convection with nitrogen gas, argon gas, or dry air.

11. The method of forming a non-reactive layer on a metal layer of a heating chamber of claim 9, wherein the reactive gases include hydrogen, nitrogen, titanium tetrachloride, and ammonia, and wherein the non-reactive layer is made of titanium nitride.

12. The method of forming a non-reactive layer on a metal layer of a heating chamber of claim 11, wherein the ratios of the reactive gases are 30˜50 vol. % for hydrogen, 30˜50 vol. % for nitrogen, 0.1˜5 vol. % for titanium tetrachloride, and 1˜25 vol. % for ammonia.

13. The method of forming a non-reactive layer on a metal layer of a heating chamber of claim 9, wherein the reactive temperature is between 600 to 700 deg. Celsius.

14. A method of forming a non-reactive layer on a metal layer of a heating chamber, comprising the steps of:
cleaning the surface of the metal layer of the heating chamber;
drying the metal layer surface by forced convection;
spraying the ceramic powders across the metal layer surface; and
heating the ceramic powders to a sintering temperature to form the non-reactive layer.

15. The method of forming a non-reactive layer on a metal layer of a heating chamber of claim 14, wherein the metal layer surface is dried by forced convection with nitrogen gas, argon gas, or dry air.

16. The method of forming a non-reactive layer on a metal layer of a heating chamber of claim 14, wherein the composition of ceramic powders is kaolin (5˜10 wt. %), feldspar (20˜80 wt. %), limestone (1˜40 wt. %), dolomite (1˜15 wt. %), wollastonite (5˜10 wt. %), corundum (1˜15 wt. %), and quartz (1˜50 wt. %), and wherein the ball-milling technique is used to form the ceramic powders and mixed uniformly.

17. The method of forming a non-reactive layer on a metal layer of a heating chamber of claim 14, wherein the non-reactive layer is a glaze.
